(19) United States
(12) Patent Application Publication
(10) Pub. No.: US 2006/0006484 A1
(43) Pub. Date: Jan. 12, 2006

(54) Functional material for micro-mechanical systems

(76) Inventors: Dilan Seneviratne, Boston, MA (US); Gregory N. Nielson, Albuquerque, NM (US); George Barbastathis, Boston, MA (US); Harry L. Tuller, Wellesley, MA (US)

Correspondence Address: GAUTHIER & CONNORS, LLP, 225 FRANKLIN STREET, BOSTON, MA, 02110, US

(21) Appl. No.: 10/915,220

(22) Filed: Aug. 10, 2004

Related U.S. Application Data
(60) Provisional application No. 60/585,647, filed on Jul. 6, 2004.

(51) Int. Cl. H01L 29/84

(52) U.S. Cl. 257/415

(57) ABSTRACT

A MEMS device includes a first material structure. A second material structure includes TiN. The second material structure is moveable relative to the first material structure.

### PRIORITY INFORMATION

This application claims priority to U.S. provisional patent application Ser. No. 60/585,647 filed Jul. 6, 2004, which is incorporated herein by reference in its entirety.

### BACKGROUND OF THE INVENTION

The invention relates to the field of micro-electro-mechanical systems, and in particular using titanium nitride (TiN) as a key active electromechanical component in micro-electro-mechanical (MEMS) devices.

In the prior art, there have been occasions in which TiN has been incorporated into MEMS devices. One such structure uses a silicon layer that is coated with highly reflective materials (aluminum, gold etc.) on both sides and wafer bonded to another wafer. The coated silicon is a tiltable mirror used for free-space optical switching. Due to interdiffusion of silicon and materials used for the highly reflective layer, a TiN film is used in between the aluminum and silicon. The use of TiN in this case, therefore, is solely as a diffusion barrier.

Another such structure uses a deformable electromechanical structure (beams) that is used to switch an RF signal channel on and off by moving from its steady-state position to its deformed state (snap down/pull-in) by the application of a voltage on the bottom actuation electrode. The deformable structure is made of silicon nitride (SiN). As a refinement to this device, a static top actuation electrode, made of materials which could include TiN (e.g. tungsten, tantalum, tantalum nitride etc.), is used to assist in releasing the deformed structure by pulling up on the beams. Hence, the use of TiN in this MEMS device is as a non-moving, fixed electrode.

However, none of the conventional structures involve the use of TiN as an active MEMS element. TiN's unique combination of mechanical, electrical and chemical properties make it a preferable material for electromechanical devices in MEMS structures.

### SUMMARY OF THE INVENTION

According to one aspect of the invention, there is provided a micro-electro-mechanical (MEMS) device. The MEMS device includes a first material structure. A second material structure includes TiN. The second material structure is moveable relative to the first material structure.

According to another aspect of the invention, there is a provided a method of forming a MEMS structure. The method includes forming a first material structure. Also, the method includes forming a second material structure includes TiN. The second material structure is moveable relative to the first material structure.

### BRIEF DESCRIPTION OF THE DRAWINGS

FIG. 1 is a table demonstrating the stiffness to density ratio of TiN relative to other materials used to form MEMS devices;

FIG. 2 is a schematic diagram illustrating a MEMS parallel plate actuator having a moveable electrode formed using TiN for displacement control and switching applications;

FIG. 3 is a schematic diagram of another embodiment of a MEMS parallel plate actuator formed using TiN for displacement control and switching applications;

FIGS. 4A-4D are schematic block diagrams illustrating one example of a fabrication process for the structures shown in FIGS. 3-4;

FIGS. 5A-5B are schematic diagrams of a MEMS piezoelectric actuator using TiN for displacement control and switching applications;

FIG. 6 is a schematic diagram of a MEMS thermal actuator structure formed from TiN for displacement control and switching applications;

FIG. 7 is a schematic diagram of another implementation of a MEMS thermal actuator structure formed from TiN for displacement control and switching applications;

FIGS. 8A-8C are schematic diagrams of another implementation of a MEMS thermal actuator structure formed from TiN for displacement control and switching applications;

FIGS. 9A-9B are schematic diagrams of a MEMS magnetic displacement/switch actuator formed using TiN for displacement control or switching applications;

FIG. 10 is a schematic diagram of a MEMS parallel plate electrostatic resonator formed from TiN for electrical filtering and clocking applications;

FIGS. 11A-11B are schematic diagrams of a MEMS piezoelectric resonator fabricated using TiN for electrical filtering and clocking applications;

FIG. 12 is a schematic diagram of a MEMS accelerometer formed with TiN that uses electrostatic comb drives for sensing and excitation;

FIG. 13 is a schematic diagram of a MEMS deformable membrane structure composed of TiN for acoustic sensing (microphone) applications;

FIG. 14 is a schematic diagram of a MEMS parallel plate structure used for capacitive energy harvesting formed using the TiN;

FIG. 15 is a schematic diagram of a MEMS piezoelectric structure using TiN for energy harvesting;

FIG. 16 is a schematic diagram of a MEMS gear train fabricated using TiN;

FIGS. 17A-17C are schematic diagrams of a MEMS tunable optical grating formed from TiN that uses parallel plate electrostatic actuators modifying the grating;

FIG. 18 is a schematic diagram of a MEMS tunable optical grating formed from TiN that uses electrostatic comb drive actuators for analog tuning of the grating period;

FIG. 19 is a schematic diagram of a MEMS tiltable micromirror formed from TiN that uses torsional electrostatic actuators to tilt the mirror back and forth;

FIGS. 20A-20B are schematic diagrams of a MEMS tunable optical grating formed using TiN that uses a piezoelectric actuator for tuning the period of the grating;

FIG. 21 is a schematic diagram of a MEMS tunable optical grating formed using TiN that uses thermal actuators for tuning the period of the grating;

FIGS. 22A-22B are schematic diagrams of a MEMS bistable switch structure formed from TiN;

FIG. 23 is a schematic diagram of a MEMS tiltable micromirror formed from TiN that uses a piezoelectric actuator to controllable tilt the mirror to different angles; and

FIGS. 24A-24B are schematic diagrams of a MEMS microfluidic valve formed from TiN that uses a parallel plate actuator to control the valve.

### DETAILED DESCRIPTION OF THE INVENTION

TiN is an unusual material in exhibiting metallic-like electrical properties while possessing ceramic-like mechanical properties. It is currently commonly used in integrated circuit fabrication as a diffusion barrier between the metallization layer and the active (semiconductor) devices. Its other common use is as a coating for machine tools to reduce wear of the machine tools. Because of its utility as a diffusion barrier in the IC industry, TiN is readily available in microfabrication facilities and much is known about deposition and etching techniques for TiN.

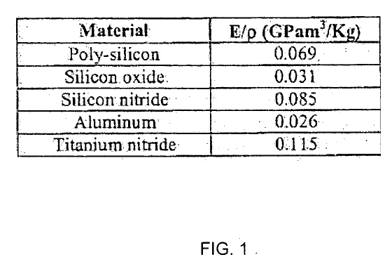

TiN has a number of properties that make it a very good material for MEMS devices. It is electrically conductive. It has a high modulus and melting point, but moderate density. Compared to other MEMS materials such as poly-silicon, silicon nitride, or the like, TiN has the highest stiffness to density ratio, as shown in FIG. 1. Due to its low surface adhesion energy, TiN naturally displays anti-stiction qualities. TiN also displays high strength, high chemical stability, high wear resistance, and high surface hardness. In addition, TiN acts as a diffusion barrier. These characteristics are all highly desirable in MEMS devices.

TiN's superior stiffness to density ratio compared to other standard MEMS materials, such as silicon, poly-silicon, aluminum, silicon nitride etc. is particularly attractive for use in MEMS. The high stiffness to density ratio translates directly into higher resonant frequencies and, therefore, faster response (i.e. switching or actuation) times than can be achieved with other materials. In addition, the high stiffness of TiN allows for a reduction in the geometrical dimensions of a given device while still maintaining the same compliance. This reduction in feature size leads to both potentially new functionality as well as lower production costs because more devices can be fabricated per wafer.

TiN also has a very low susceptibility to creep in free-standing structures and is thus very desirable for use in MEMS devices. Creep causes performance of devices to drift with time and usage. This reduces the useful lifetime of products, if the products are acceptable at all. Creep does occur with MEMS fabricated out of current MEMS materials, all the more so, as the operation temperature is increased. Creep would be largely eliminated in MEMS devices through the use of TiN.

The non-stick nature of TiN is beneficial in electromechanical structures that are designed to pull-in and subsequently revert back to their original position as in micro-relays. It would also be beneficial in fabrication of MEMS devices, potentially allowing the removal of sacrificial layers using techniques (such as wet etching) that would otherwise lead to stiction thus simplifying the fabrication process. Having a non-stick surface prevents stiction when structures come into contact with other materials and surfaces. Thus, using TiN in such cases may eliminate the need for additional steps commonly taken to prevent stiction such as complex or uncommon release etch processes, the addition of anti-stiction bumps, or the deposition of anti-stiction films and monolayers.

In structures that come into contact with other surfaces, it is desirable to use a material with a higher hardness and abrasion resistance so that such structures do not become damaged from periodic contact. TiN has very high hardness and abrasion resistance. It is commonly used as a coating on machine tools to prevent wear. These qualities should translate into longer lifetimes and better reliability for MEMS devices where there is periodic contact between surfaces.

The ultimate (fracture) strength of TiN is very high. This property is important for a number of reasons. First, because of this property TiN can be used in applications that require materials that can handle high stress. Second, the high strength of TiN allows structures to be able to withstand unusual stress situations that do not occur in normal operation (i.e. drop tests). Finally, the high strength provides device robustness during the fabrication process, allowing more stressful process steps to be used with success.

The chemical stability of TiN allows devices fabricated out of TiN to be used in environments that may not be feasible for other MEMS materials. This is important for applications such as pressure sensors, micro-valves, and micro-motors where the MEMS material comes into direct contact with a variety of chemicals. This property also minimizes the effects of aging for virtually all applications.

The melting point of TiN is very high. This allows the use of TiN at much higher temperatures than many other MEMS materials. The high melting temperature allows TiN to maintain many of its important characteristics, such as high stiffness and strength as well as creep resistance, at elevated temperatures. This is a good property to have in general but this is specifically important for micro-motors, pressure sensors, and micro-reactors.

In addition to these desirable mechanical and chemical properties, TiN is electrically conductive. This allows structures fabricated out of TiN to be used for various actuation methods that require electrical functionality, such as electrostatic, thermal, piezoelectric, and magnetic actuation. To achieve this combination of mechanical performance and electrical behavior, MEMS designers in the past have used structures composed of two or more materials. For instance, silicon nitride and aluminum bilayers have been used to provide high stiffness and conductive structures. One drawback to this approach is that stress induced bending of the bilayers commonly arises due to the thermal-mechanical mismatch between the different materials. A structure with comparable or better capabilities would be much more easily obtained by using only TiN. The electrical conductivity of TiN is a key benefit of using TiN.

Fabrication techniques for TiN are similar to other materials used in microfabrication. It can be deposited in a variety of ways including both high and low temperature processes. It can be annealed to relieve residual stress. For sputter deposited TiN films, annealing can be achieved at temperatures as low as 300° C. For other deposition techniques, annealing does not begin until approximately 1300° C. Etching can be accomplished with both wet etching techniques and reactive ion etching (RIE) techniques. These techniques are commonly used in the integrated circuit and machine tool coating industries.

TiN would be useful in a wide range of MEMS devices including, but not limited to, electrostatic switches (optical, electrical (DC through RF), etc.), piezoelectric switches (optical, electrical (DC through RF), etc.), thermally actuated switches (optical, electrical (DC through RF), etc.), magnetically actuated switches (optical, electrical (DC through RF), etc.), electrostatic resonators, piezoelectric resonators, accelerometers, microphones, energy harvesting devices (mechanical (i.e. vibrational) energy to electrical energy), energy conversion devices (motors—chemical to mechanical energy), gear trains, electrostatically actuated optical gratings, piezoelectrically actuated optical gratings, thermally actuated optical gratings, bistable mechanisms, electrostatically actuated micromirrors, piezoelectrically actuated micromirrors, and valve structures for microfluidic systems.

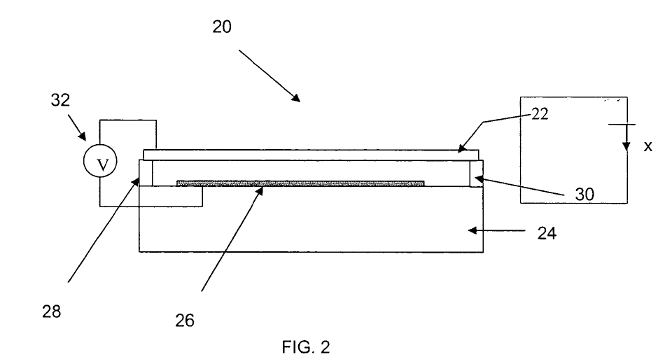

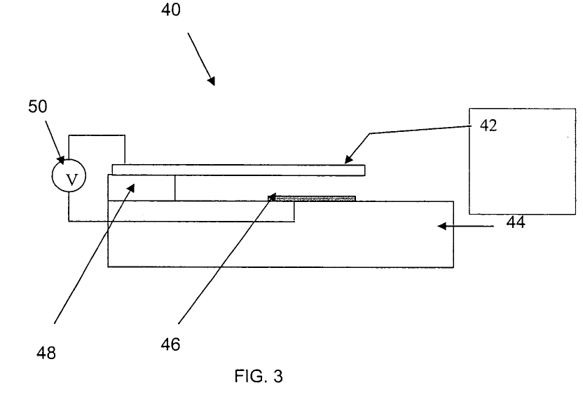

Two possible implementations 20, 40 of a parallel plate electrostatic actuator formed from TiN for displacement control and switching applications are depicted in FIGS. 2 and 3. TiN can form both the fixed 26, 46 and moving electrodes 22, 42 for these actuators 20, 40. Also, the actuators 20, 40 include voltage sources 32, 50 to provide the necessary voltage for proper operation. The fixed electrodes 26, 46 are fabricated on top of the substrate 24, 44 (usually silicon with a thin dielectric film). The moving electrodes 22, 42 are suspended above the fixed electrodes 26, 46 by anchors 28, 48 that provide electrical isolation between the moving and fixed electrodes. Electrical leads, optical waveguides, or other structures can be added to this structure to provide switch functionality in various physical domains.

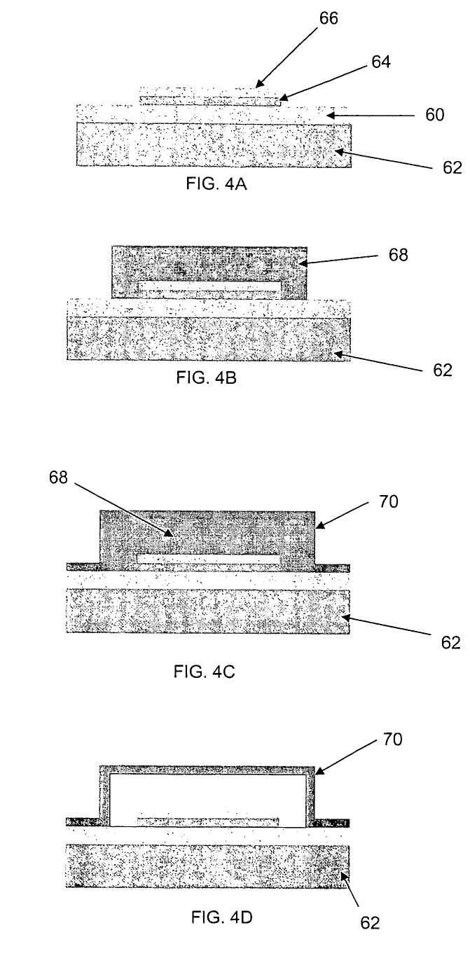

A possible fabrication approach for a parallel plate actuator formed from TiN is shown in FIGS. 4A-4D. Standard CMOS (microelectronic) processing methods can be used to fabricate MEMS devices having TiN. For example, the fabrication of the structures 20, 40 would involve depositing an insulating layer 60, e.g. silicon dioxide (SiO₂) that was formed on a substrate 62, as shown in FIG. 4A. Moreover, a poly-silicon layer 64 is deposited on the insulating layer 60. A second insulating layer 66 is deposited on the poly-silicon layer 64. Afterwards, a sacrificial layer 68 is deposited and encompasses the layers 66, 68 and a portion of the insulating layer 60, as shown in FIG. 4B. A TiN layer 70 is deposited on the sacrificial layer 68. In depositing the TiN layer 70, electron-beam evaporation, sputtering and chemical vapor deposition can be used, as shown in FIG. 4C. The TiN layer 70 is released by removing the sacrificial layer 68, as shown in FIG. 4D.

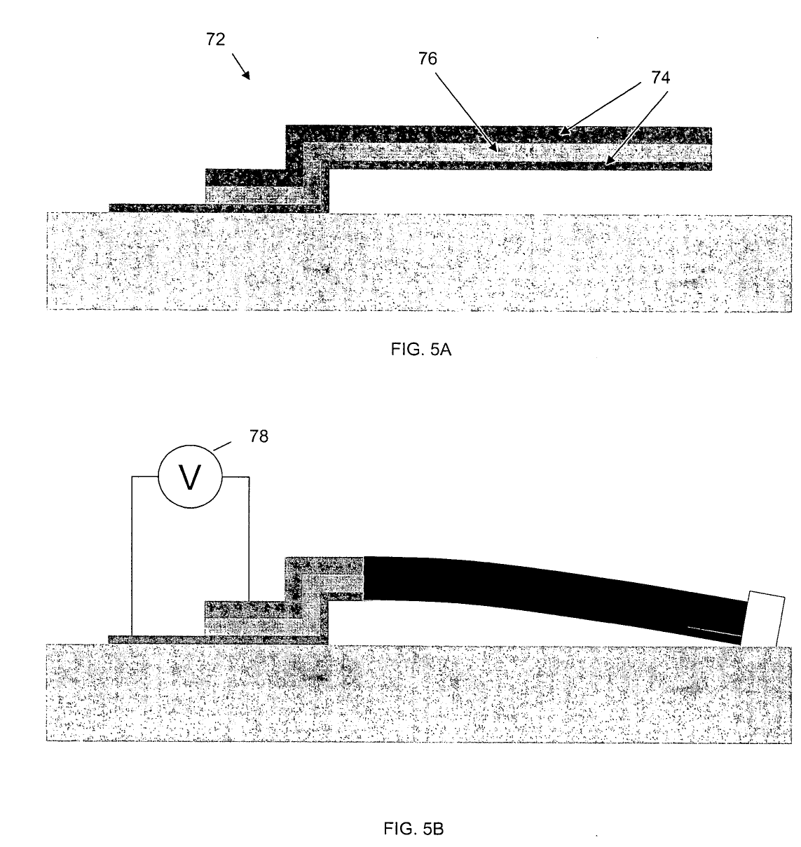

One possible implementation of a piezoelectric actuator 72 is shown in FIG. 5A. This actuator 72 could be used in displacement control or switching applications. In this actuator 72, the electrodes 74 are formed with TiN, and are on either side of the piezoelectric material 76. In addition to acting as electrodes, the TiN 74 also acts as an adhesion layer and diffusion barrier (depending on the type of piezoelectric material). The TiN also provides the necessary mechanical structure for the actuator 72. FIG. 5B shows the actuator 72 being displaced after the application of a voltage from a voltage source 78. Electrical leads, optical waveguides, or other structures can be added to this switching structure 72 to give the switch functionality in various physical domains.

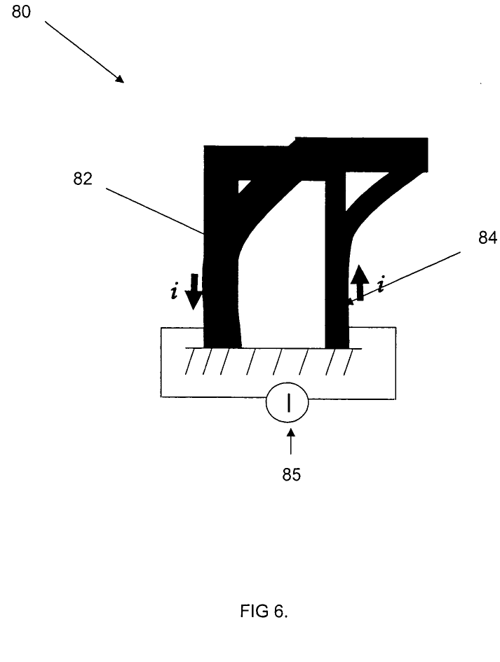

Three possible implementations of a thermal actuator are shown in FIGS. 6-8. These actuators can be used for displacement control or switching applications. For the implementation 80 shown in FIG. 6, the entire thermal actuator is formed with TiN. The actuator 80 includes two leg beams 82, 84 that create an input and return path for a current source 85. Note the leg beams 82, 84 have different cross-sectional areas, and therefore different electrical resistance. The smaller beam 84 therefore heats up and expands more than the thicker beam 82, which creates motion.

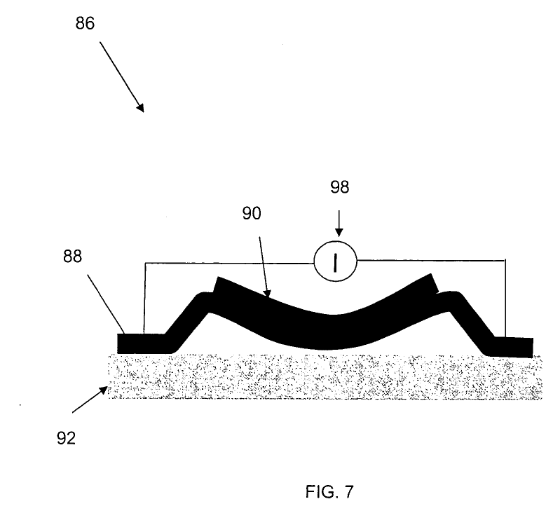

The thermal actuator implementation 86 shown in FIG. 7 uses a bi-material structure. One of the materials used in the bi-material actuator is TiN 88. The second material 90 is selected to be a material with a much different coefficient of thermal expansion. An electrical current source 98 flows an electric current through the TiN 88 which provides heat for the actuator due to the electrical resistance in the TiN. The thermal actuator 86 is fabricated on and anchored to a substrate 92 (usually silicon).

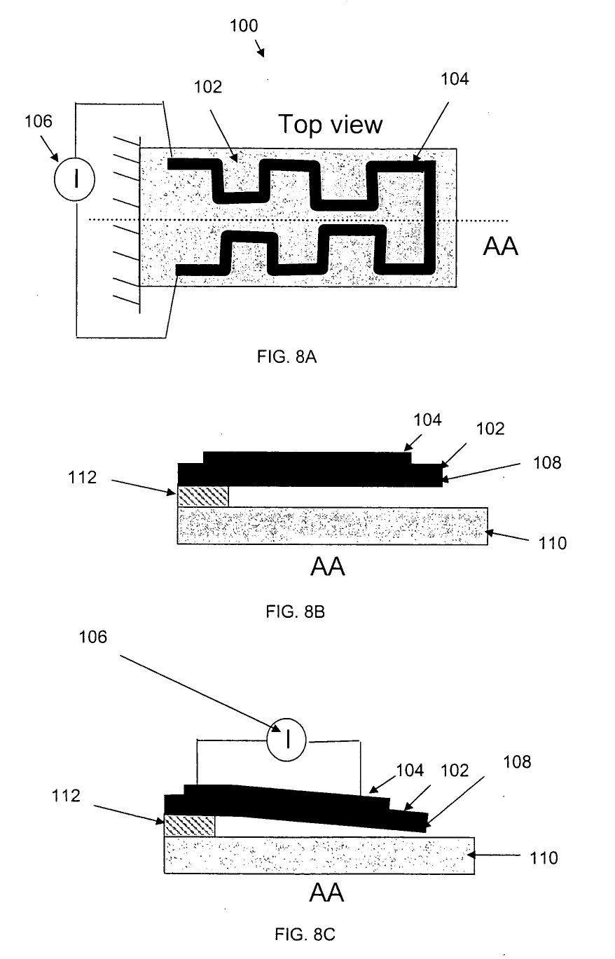

The thermal actuator implementation 100 shown in FIG. 8A also uses a bi-material structure. TiN can be used for one of the materials 108 in the structure 100 (FIG. 8B). The second material 102 is a material with a coefficient of thermal expansion that is different than TiN. The resistive heater 104 on top of the structure can also be made of TiN. When an electrical current source 106 flows a current through the resistive heater 104, the temperature of the bi-material structure 100 is raised which leads to a deflection of the structure 100 as in FIG. 8C. The structure is fabricated on and anchored to a substrate 110 (usually silicon). Electrical leads, optical waveguides, or other structures can be added to these thermal actuators to provide switch functionality in various physical domains.

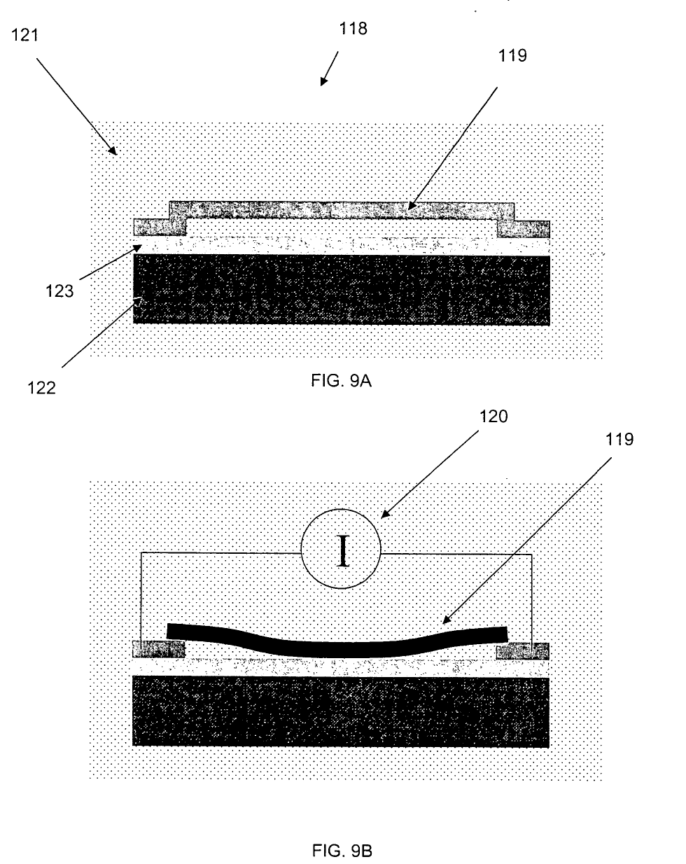

One possible implementation of a magnetic actuator 118 is shown in FIGS. 9A-9B. This structure 118 can be used for displacement control and switch applications. The actuator 118 includes a bridge 119 that is fabricated on a substrate 122 that includes an insulating layer 123. Also, a magnetic field 121 is applied that is directed out of the plane where actuator 118 is positioned. FIG. 9B shows a current source 120 that supplies current to the bridge 119, which causes displacement as shown.

For the actuator 118, the TiN provides both the structural element 119 as well as the electrical pathway for the current that causes the actuation in the magnetic field via Lorentz forces. Electrical leads, optical waveguides, or other structures can be added to this structure to provide switch functionality in various physical domains.

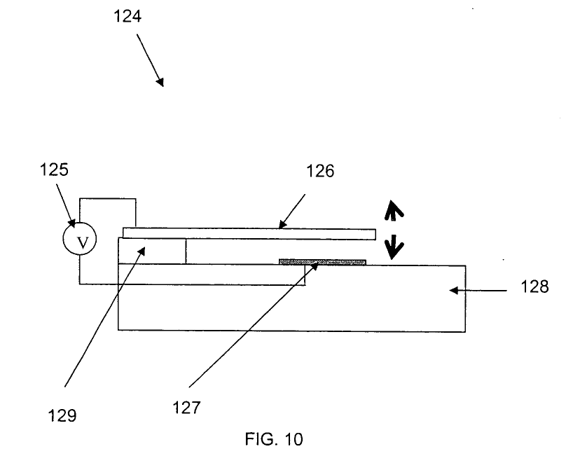

FIG. 10 shows one possible implementation of an electrostatic resonator 124 using the invention. Note the resonator structure is similar to the structure described in FIG. 3. The fixed electrode 127 and the moving (resonating) electrode 126 can both be fabricated out of TiN. The fixed electrode 127 is fabricated directly on the substrate 128. The moving electrode 126 is suspended above the substrate by an anchoring material 129. The excitation of the resonator is provided by an electrical signal source 125. This device would be used in electrical filtering and clocking applications.

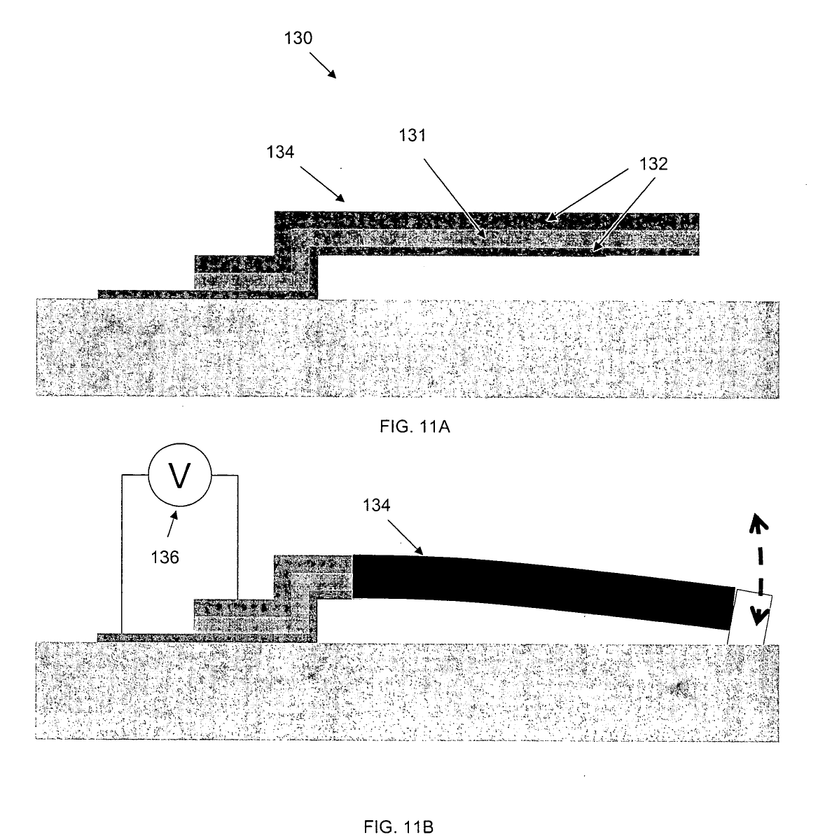

FIG. 11A shows a piezoelectric resonator 130 that is formed using TiN. In this implementation, the resonator 130 includes an electromechanical structure 134 that includes electrodes 132, which are formed with TiN. The electrodes 132 surround the piezoelectric material 131. The electrodes 132 provide for electrical excitation and sensing of the resonator 130 as well as act as structural elements and a diffusion barrier for the piezoelectric material 131. FIG. 11B shows the structure 134 under mechanical motion when a voltage is applied by a voltage source 136. Uses for the structure 130 include electrical filtering and clocking applications.

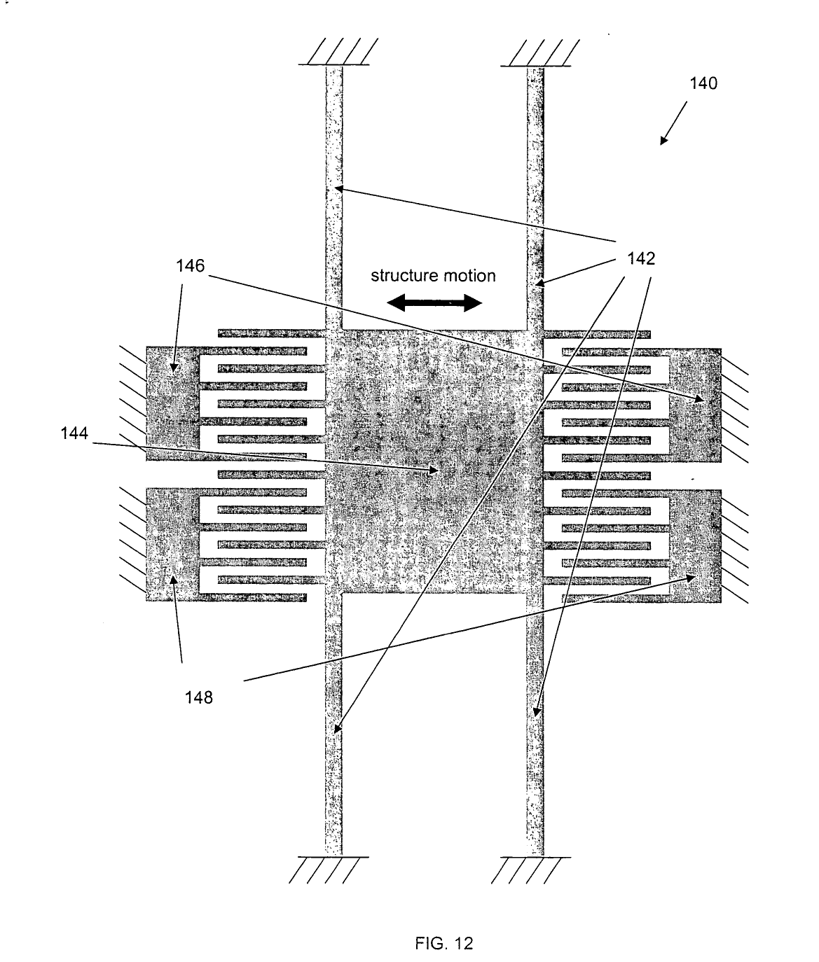

FIG. 12 shows an accelerometer 140 formed in accordance with the invention. In this implementation, the TiN is used to create the springs or flexures 142, the mass 144, and the comb electrodes 146, 148 for sensing and excitation. When the mass 144 is subjected to an acceleration, the springs 142 allow the mass 144 to displace. The displacement is sensed by one of the two sets of comb electrodes 146, 148. The second set of electrodes 148 is used to maintain the position of the mass and to provide a self test of the functionality of the device.

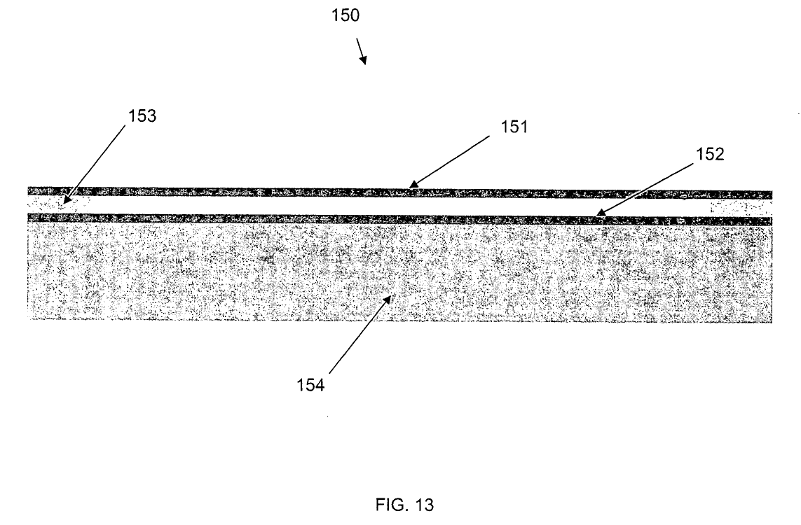

FIG. 13 shows a microphone (vibration sensor) 150 formed in accordance with the invention. In this implementation, TiN is used to create the membrane 151 that is excited by the acoustic vibrations. The TiN membrane 151 is suspended over a second, fixed electrode 152, which also could be made of TiN, for sensing of the vibrations in the membrane. The fixed electrode 152 is fabricated on top of a substrate 154 while the membrane 151 is suspended by non-conducting anchors 153.

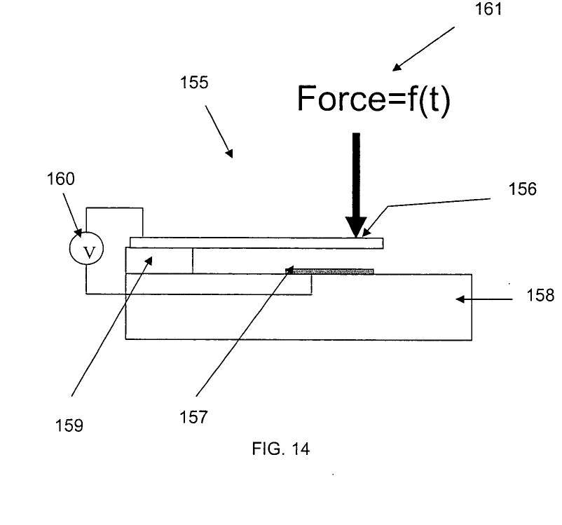

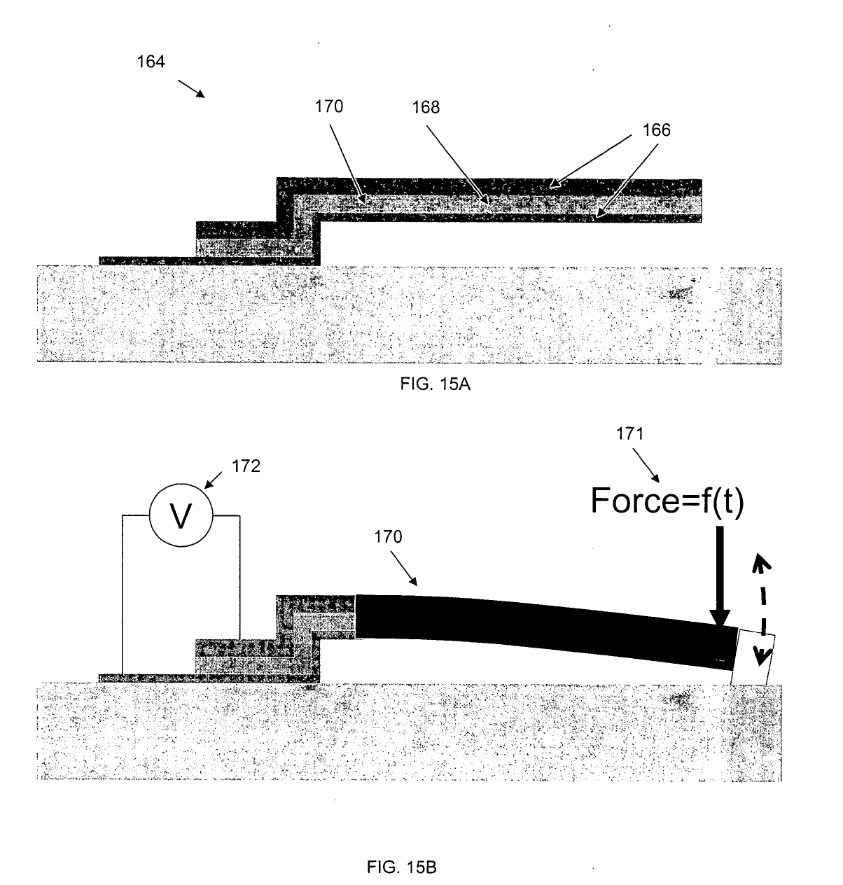

Two possible implementations of energy harvesting devices are shown in FIGS. 14 and 15A-15B. In the implementation 155 shown in FIG. 14 the energy is harvested by creating a capacitor out of two electrodes 156 and 157. On electrode 157 is fixed to the substrate 158 while the second electrode 156 is suspended above the fixed electrode by anchors 159. The suspended electrode 156 vibrates as a result of external disturbances 161. Electrical energy is created by applying a voltage 160 to the two electrodes 156, 157 and extracting the current that flows due to the mechanical vibrations of the suspended electrode 156. Either or both of the electrodes 156, 157 could be beneficially composed of TiN, providing the necessary mechanical and electrical capabilities.

In the second implementation shown in FIGS. 15A-15B, the energy harvester 164 is a piezoelectric cantilever 170 that includes electrodes 166 that are formed with TiN and piezoelectric material 168 in between the electrodes 166. The cantilever 170 vibrates as a result of external disturbances 171 which produces a voltage 172 and current between the electrodes 166 as shown in FIG. 15B. From the current, energy is extracted from the device 164.

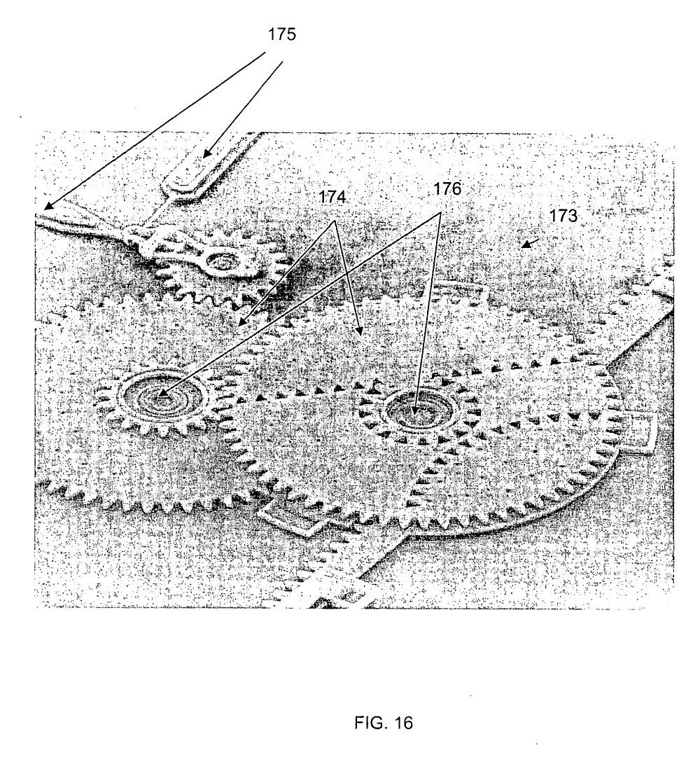

One implementation of a gear train 173 is shown in FIG. 16. In this implementation, both the gears 174 and the axels 176 around which the gears 174 turn could be fabricated out of TiN. The anti-stiction and wear resistance of TiN would prove very important in this application. This gear train 173 is driven by a linear motion actuator (such as an electrostatic comb drive actuator) through the links 175. Both the mechanical links and the electrostatic comb drive actuator can be fabricated out of TiN.

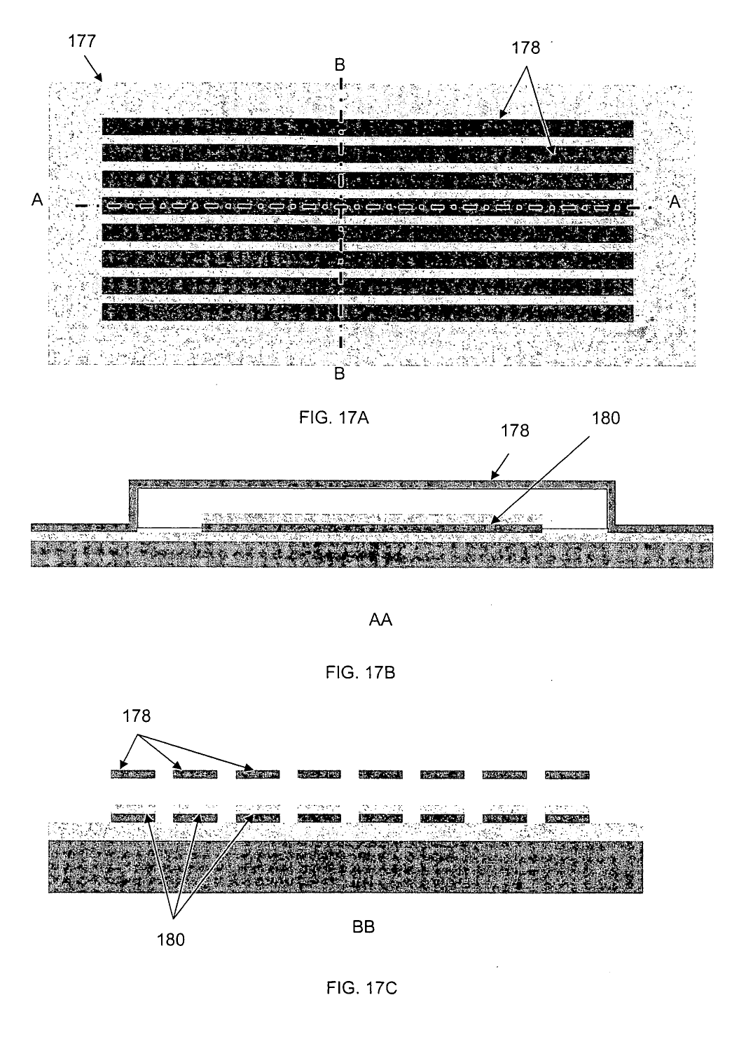

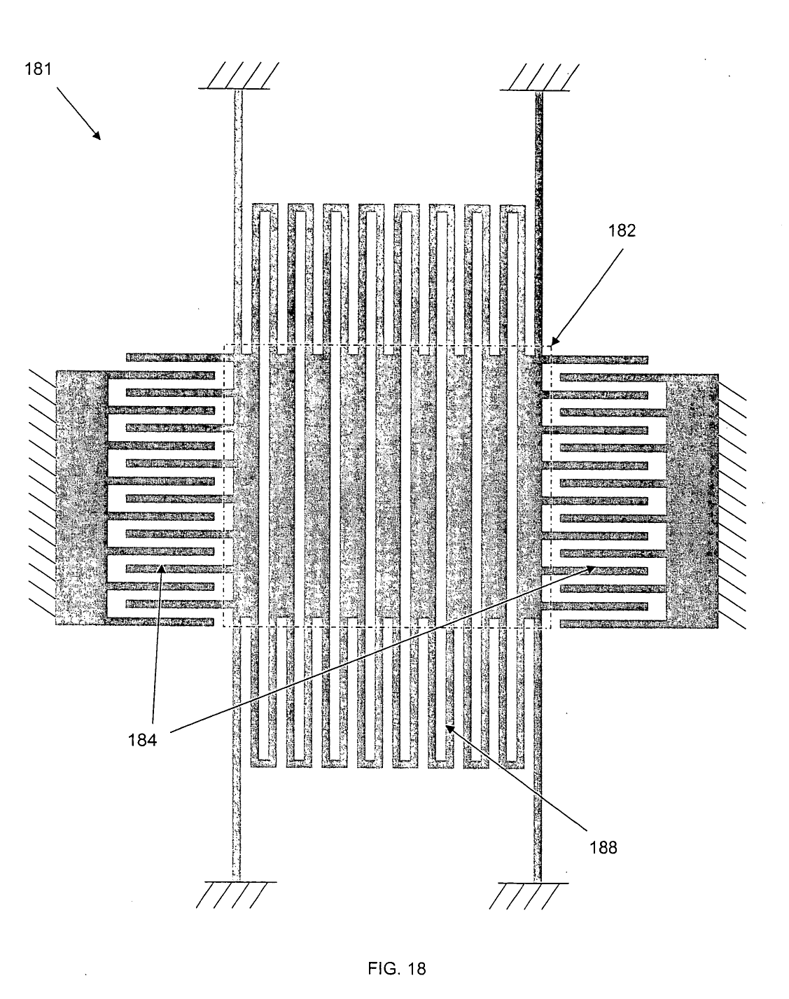

Two implementations of electrostatically actuated optical gratings are shown in FIGS. 17A-17C and 18. In the implementation shown in FIG. 17A, the grating 177 is created by long and narrow suspended electrodes 178 made of TiN. These electrodes 178 are formed over fixed electrodes 180 that could also be TiN. The suspended electrodes 178 are pulled to different heights by applying different voltages to create adaptive optical gratings. FIG. 17B shows a cross-section view of the grating 177 along the A-A direction, and FIG. 17C show a cross-section view of the grating 177 along the B-B direction.

In the second implementation 181 shown in FIG. 18 is fabricated completely out of TiN. The grating 182 is a structure that moves in plane by being stretched apart by electrostatic comb drives 184 on either side of the grating 182. This causes the period of the grating 182 to change, allowing the grating 182 to be adaptive. The flexures 188 that connect the beams that form the grating 182 allow large displacements with the relatively small force provided by the comb drive actuators. A thin layer of aluminum or gold could be deposited on the surface of either device 177, 181 to enhance the optical reflectivity of the structures.

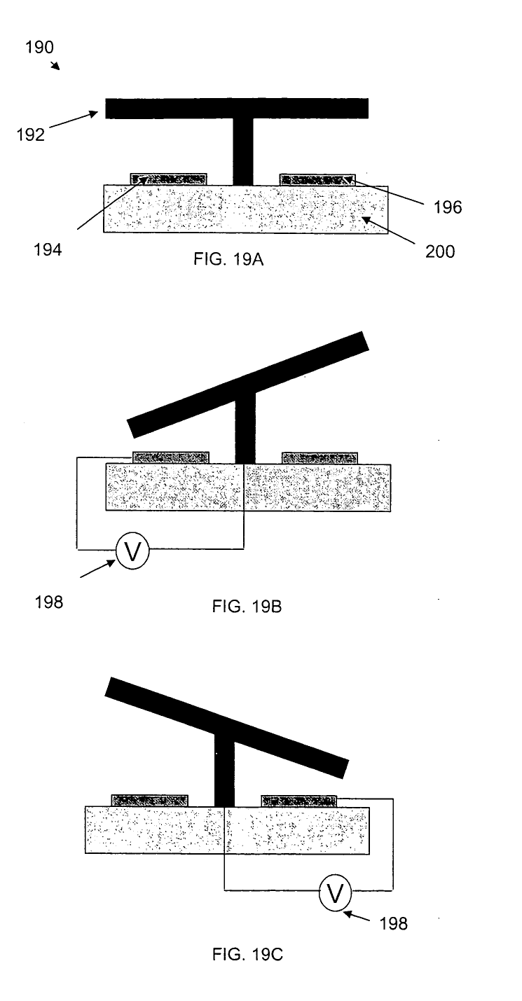

FIG. 19A shows an electrostatically actuated micromirror 190. In this instance, the TiN provides the mechanical material for the mirror 192 which is also the moving electrode. There are an additional two fixed electrodes 194, 196 which can be fabricated out of TiN and are fixed to the substrate 200. A voltage 198 is applied between the movable mirror electrode 192 and one or the other of the two fixed electrodes 194, 196 to cause the mirror to tip in one direction or the other, as in FIGS. 19B and 19C. A thin layer of aluminum or some other reflective material is coated on top of the TiN to provide the necessary reflectivity.

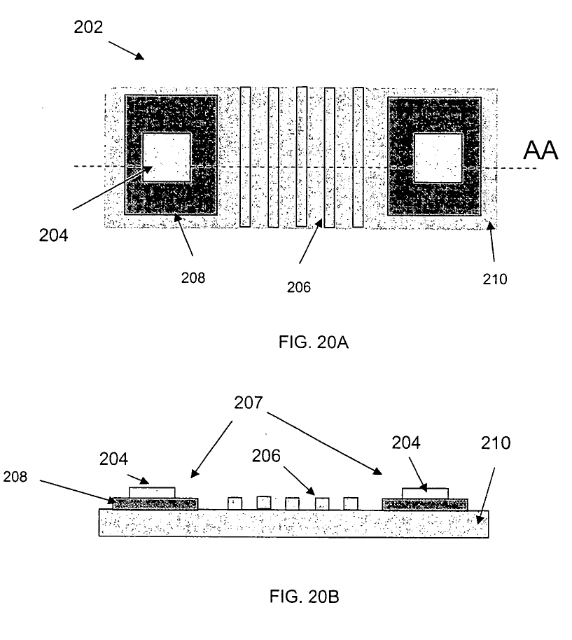

FIGS. 20A-20B shows a piezoelectrically actuated optical grating structure 202. In this case, the piezoelectric actuator 207 is created by piezoelectric material 208 that is sandwiched between TiN layers 204, 210 that form the electrodes to cause the piezoelectric material to deform. These actuators 207 stretch a TiN membrane 210 that has the optical grating 206 in it. This grating 206 could also be TiN with a thin layer of aluminum to enhance reflectivity. FIG. 20B shows a cross-section view of the structure 202 along the A-A direction.

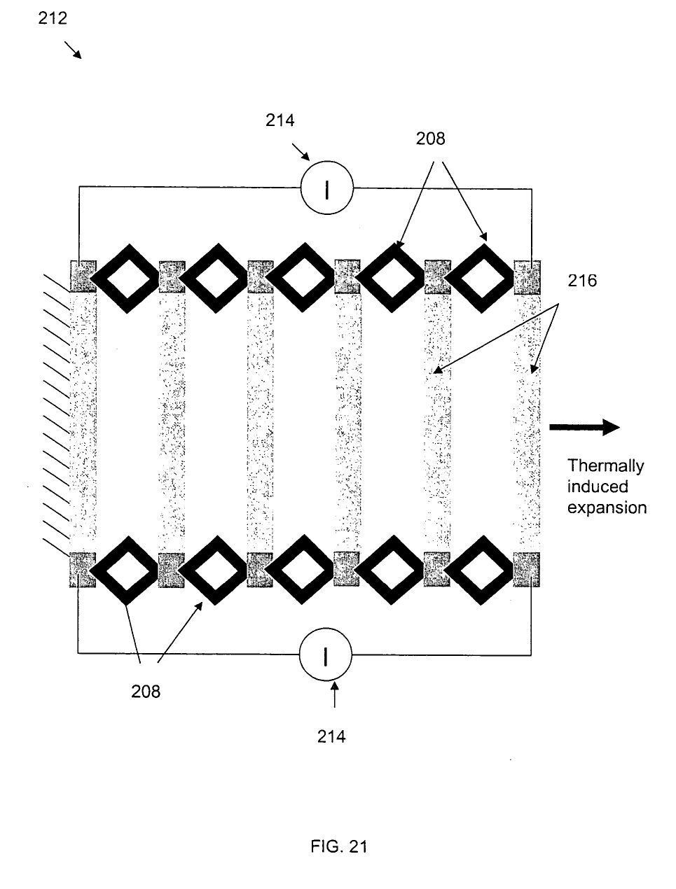

FIG. 21 shows a thermally actuated optical grating structure 212. The thermal actuation is due to the TiN structure 218 conducting a current, using current sources 214, that causes the structure 212 to heat up and expand. The thermal expansion is enhanced in the direction perpendicular to the grating by the shape of the TiN structure 218 such that the period of the grating becomes larger. The structure of the grating 216 could also be TiN coated with aluminum or another reflective material. Electrical isolation would need to be provided for between the thermal actuators on either side of the grating 212.

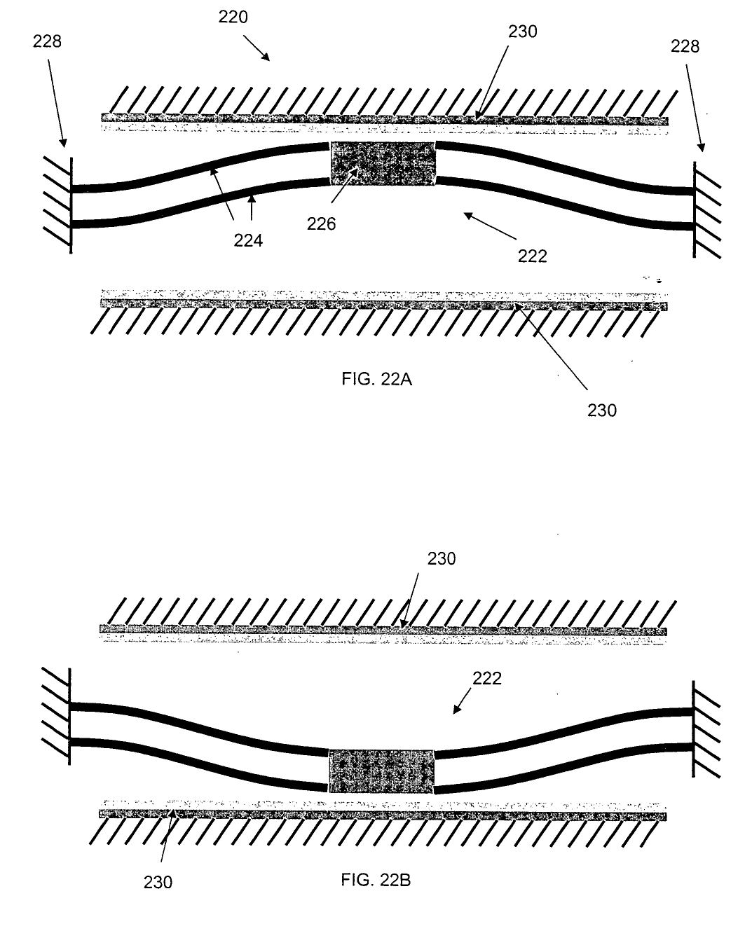

FIG. 22A shows a bistable mechanism 220. This mechanism 220 can be almost completely created out of TiN. For the electrostatic actuation shown, a thin layer of a dielectric material would be needed between the movable electrode 222 and the fixed electrodes 230. The movable electrode is created by a central, solid link 226, with a double flexure structure 224 connecting it to the anchor points 228. The double flexures 224 allow the bistable mechanism to move between the two stable positions as shown in FIG. 22B.

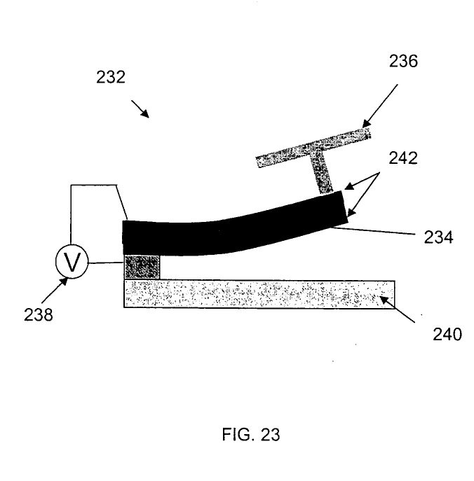

FIG. 23 shows a piezoelectrically actuated micromirror structure 232. The structure 232 includes electrodes 242 created out of TiN that sandwich the piezoelectric layer 234. Moreover, the structure 232 includes a mirror substructure 236 that is formed with TiN. The mirror substructure 236 is coated with aluminum or some other reflective material to achieve the necessary reflectivity. The entire structure is anchored to a substrate 240. A voltage source 238 provides voltage to the TiN electrodes 242. The electrodes 242 in turn create an electric field in the piezoelectric layer 234 which causes a mechanical deformation to occur, leading to a displacement of the micromirror.

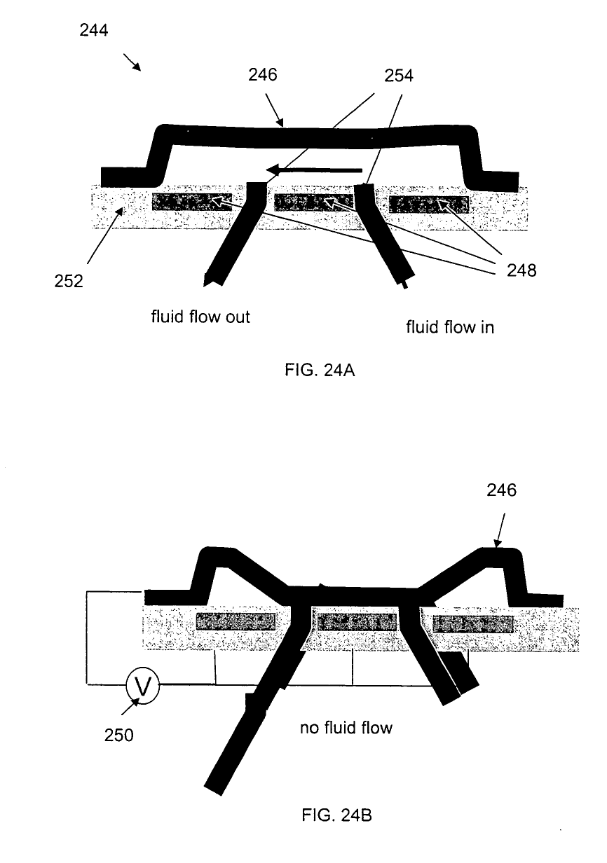

FIGS. 24A-24B shows a valve structure 244 for microfluidic systems. The valve 244 is actuated with electrostatic actuation, as shown in FIG. 24A. The top movable electrode 246 is formed from TiN. The bottom electrodes 248 are fixed to the substrate 252. The substrate 252 has microfluidic channels 254 to conduct the fluid to and from the valve. When a voltage 250 is applied between the movable electrode 246 and the fixed electrodes 248, the valve is close, as in FIG. 24B, and the fluid is no longer able to flow through the valve.

Although the present invention has been shown and described with respect to several preferred embodiments thereof, various changes, omissions and additions to the form and detail thereof, may be made therein, without departing from the spirit and scope of the invention.

What is claimed is:

1. A micro-electro-mechanical (MEMS) device comprising:
a first material structure; and
a second material structure comprising TiN, said second material structure is moveable relative to said first material structure.

2. The MEMS device of claim 1, wherein said first material structure comprises TiN.

3. The MEMS device of claim 1, wherein said first material structure comprises SiN.

4. The MEMS device of claim 1, wherein said first and second material structures are positioned to form a cantilever MEMS structure.

5. The MEMS device of claim 1, wherein said second material structure comprises sufficient composition of TiN to prevent stiction with said fixed material structure.

6. The MEMS device of claim 1, wherein said second material structure comprises piezoelectric material.

7. The MEMS device of claim 1, wherein said first and second material structures form a thermal actuator arrangement.

8. The MEMS device of claim 1, wherein said first and second material structures form a magnetic actuator arrangement.

9. The MEMS device of claim 8, wherein said first material structure comprises a dielectric layer.

10. The MEMS device of claim 8, wherein said second material structure comprises a bridge structure.

11. The MEMS device of claim 1, wherein said first and second material structures form a piezoelectric structure.

12. The MEMS device of claim 11, wherein said first material structure comprises a piezoelectric material.

13. The MEMS device of claim 11, wherein said second material structure comprises at least two electrodes.

14. The MEMS device of claim 1, wherein said first material structure and second material structures form a piezoelectric structure.

15. The MEMS device of claim 14, wherein said first material structure comprises springs or flexures and a mass structure that comprise of TiN.

16. The MEMS device of claim 11, wherein said second material structure comprises a plurality of comb electrodes.

17. The MEMS device of claim 1, wherein said first and second material structures form a vibrator sensor.

18. The MEMS device of claim 17, wherein said first material structure comprises a fixed electrode.

19. The MEMS device of claim 17, wherein said second material structure comprises a membrane that is excited by the acoustic vibrations.

20. The MEMS device of claim 1, wherein said first and second material structures form a energy harvesting structure.

21. The MEMS device of claim 20, wherein said first material structure comprises a piezoelectric material.

22. The MEMS device of claim 20, wherein said second material structure comprises at least two electrodes.

23. The MEMS device of claim 1, wherein said first and second material structures form a grating structure.

24. The MEMS device of claim 23, wherein said first material structure comprises a plurality of electrodes.

25. The MEMS device of claim 23, wherein said second material structure comprises a plurality of electrodes.

26. The MEMS device of claim 1, wherein said first and second material structures form an electrostatically actuated micromirror.

27. The MEMS device of claim 26, wherein said first material structure comprises a plurality of electrodes.

28. The MEMS device of claim 26, wherein said second material structure comprises a mirror.

29. The MEMS device of claim 23, wherein said second material structure comprises a piezoelectric material.

30. The MEMS device of claim 23, wherein said grating structure conducts electricity.

31. The MEMS device of claim 1, wherein said first and second material structures form an electrostatically actuated micromirror.

32. The MEMS device of claim 31, wherein said first material structure comprises a piezoelectric material.

33. The MEMS device of claim 31, wherein said second material structure comprises at least two electrodes.

34. The MEMS device of claim 31 further comprises a mirror coupled to one of said at least two electrodes.

35. A method of forming a micro-electro-mechanical (MEMS) device comprising:
forming a first material structure; and
forming a second material structure comprising TiN, said second material structure is moveable relative to said first material structure.

36. The method of claim 35, wherein said first material structure comprises TiN.

37. The method of claim 35, wherein said first material structure comprises SiN.

38. The method of claim 35, wherein said first and second material structures are positioned to form a cantilever MEMS structure.

39. The method of claim 35, wherein said second material structure comprises sufficient composition of TiN to prevent stiction with said fixed material structure.

40. The method of claim 35, wherein said second material structure comprises piezoelectric material.

41. The method of claim 35, wherein said first and second material structures form a thermal actuator arrangement.

42. The method of claim 35, wherein said first and second material structures form a magnetic actuator arrangement.

43. The method of claim 42, wherein said first material structure comprises a dielectric layer.

44. The method of claim 42, wherein said second material structure comprises a bridge structure.

45. The method of claim 35, wherein said first material structure and second material structures form a piezoelectric structure.

46. The method of claim 45, wherein said first material structure comprises a piezoelectric material.

47. The method of claim 45, wherein said second material structure comprises at least two electrodes.

48. The method of claim 35, wherein said first material structure and second material structures form a piezoelectric structure.

49. The method of claim 49, wherein said first material structure comprises springs or flexures and a mass structure that comprise of TiN.

50. The method of claim 45, wherein said second material structure comprises a plurality of comb electrodes.

51. The method of claim 35, wherein said first material structure and second material structure form a vibrator sensor.

52. The method of claim 51, wherein said first material structure comprises a fixed electrode.

53. The method of claim 51, wherein said second material structure comprises a membrane that is excited by the acoustic vibrations.

54. The method of claim 35, wherein said first material structure and second material structure form a energy harvesting structure.

55. The method of claim 54, wherein said first material structure comprises a piezoelectric material.

56. The method of claim 54, wherein said second material structure comprises at least two electrodes.

57. The method of claim 35, wherein said first material structure and second material structure form a grating structure.

58. The method of claim 57, wherein said first material structure comprises a plurality of electrodes.

59. The method of claim 57, wherein said second material structure comprises a plurality of electrodes.

60. The method of claim 35, wherein said first and second material structures form an electrostatically actuated micromirror.

61. The method of claim 60, wherein said first material structure comprises a plurality of electrodes.

62. The method of claim 60, wherein said second material structure comprises a mirror.

63. The method of claim 57, wherein said second material structure comprises a piezoelectric material.

64. The method of claim 57, wherein said grating structure conducts electricity.

65. The method of claim 35, wherein said first and second material structures form an electrostatically actuated micromirror.

66. The method of claim 65, wherein said first material structure comprises a piezoelectric material.

67. The method of claim 65, wherein said second material structure comprises at least two electrodes.

68. The method of claim 65 further comprises coupling a mirror to one of said at least two electrodes.
